(19) United States
(12) Patent Application Publication
(10) Pub. No.: US 2006/0220198 A1
(43) Pub. Date: Oct. 5, 2006

(54) Semiconductor integrated circuit (IC) packaging with carbon nanotubes (CNT) to reduce IC/package stress

(76) Inventor: Rajashree Baskaran, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/095,856

(22) Filed: Mar. 30, 2005

(51) Int. Cl. H01L 23/495

(52) U.S. Cl. 257/678

(57) ABSTRACT

A packaged integrated circuit (IC) is described having an integrated circuit that is electrically coupled to its package's wiring with Carbon nanotubes (CNTs) placed within an electrically conductive material.

### FIELD OF INVENTION

The field of invention relates generally to semiconductor integrated circuit (IC) packaging; and, more specifically, to semiconductor integrated circuit (IC) packaging with Carbon nanotubes (CNTs) to reduce IC/package stress.

### BACKGROUND

FIG. 1 shows a cross section of a semiconductor integrated circuit (IC) 101 that has been packaged into a ball-grid-array package 102. A semiconductor IC, which is also frequently referred to as a “semiconductor chip” or simply as a “die”, is a piece of semiconductor substrate material 102 that has been processed so as to include: 1) transistors (not shown in FIG. 1) embedded within the semiconductor substrate material 102; and, 2) a multi-layer structure 103 of metal wiring and dielectric that “sits” upon the semiconductor substrate material (if the semiconductor substrate material 102 is viewed as being beneath the multi-layer structure 103 (which is exactly opposite from the perspective depicted in FIG. 1)).

The multi-layer structure 103 essentially forms a plurality of wires, most of which are typically used to “interconnect” the transistors embedded within the semiconductor substrate material 102. However, semiconductor ICs are typically not meant to operate in a perfectly isolated fashion, and, as such, at least some of the wires built within the multi-layer structure 103 are electrically coupled to structures designed to pass electrical signals, supply voltage(s) and/or reference voltage(s) into and/or out of the semiconductor IC 101 (often collectively referred to as “I/Os”). FIG. 1 shows one such structure 104 which is often referred to as a “ball” or “bump”. Balls or bumps may have additional descriptive terms that typically describe their material composition (e.g., “solder bump”, “solder ball”, “copper bump”, “gold bump”) and/or bonding dynamics (e.g., “C4 bump”, etc.).

The bump 104 is typically: 1) formed as part of the semiconductor IC 101 manufacturing process; 2) electrically conductive; and, 3) electrically coupled to at least one wire within multi-layer structure 103 (such as wire 105). By disposing many bumps such as bump 104 across the surface 106 of the semiconductor IC 101, the semiconductor IC 101 can entertain a large number of I/Os.

The semiconductor IC 101 is typically manufactured according to a first process, and then, is packaged according to a second process (the “packaging” process). The packaging process involves fixturing the semiconductor IC into a package that behaves as a protective enclosure for the semiconductor IC 101. FIG. 1 shows a cross section of a hermetically sealed package that includes a ceramic lid 108 and a substrate 109. During the course of the packaging process, the semiconductor IC 101 is first affixed to the package substrate 109, then, the lid 108 is affixed to the package substrate 109 to effectively seal the semiconductor IC within its protective enclosure.

The package substrate 109 includes pads (or other structures) used to make electrical connections to the semiconductor IC's “bumps”. These pads are electrically coupled to wiring built into the package substrate 109 that flows to the packages own I/Os. FIG. 1 shows a single example of these features in relation to bump 104. Here, bump 104 makes electrical and mechanical contact to pad 110 which is electrically coupled to wiring 111. Wiring 111 runs to “ball” 112. In implementation an array of balls may be located at the bottom 113 of the package substrate 109, where, each ball is electrically coupled to a semiconductor IC bump. The entire package including the semiconductor IC can then be integrated into a larger electronic system by soldering the balls to appropriate electrical contacts within the system (e.g., by soldering the balls to pads on a “planar” board designed to receive the packaged semiconductor IC).

### FIGURES

The present invention is illustrated by way of example, and not limitation, in the figures of the accompanying drawings in which like references indicate similar elements and in which:

FIG. 1 (prior art) shows a packaged semiconductor IC;

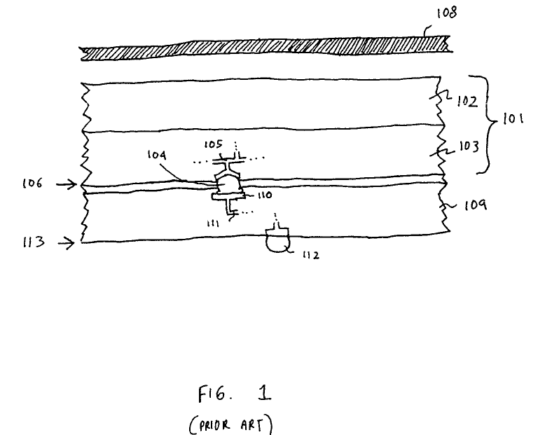

FIGS. 2a and 2b (prior art) show the bonding of a semiconductor IC bump to a package substrate pad;

FIGS. 3a and 3b show an improved semiconductor IC-to-package substrate bonding structure and process that employs CNTs inserted into a liquid solder;

FIG. 4 shows a methodology that FIGS. 3a and 3b can be viewed as demonstrating an embodiment of;

FIGS. 5a and 5b show depictions of specific semiconductor IC-to-package substrate bonding structure;

FIG. 6 shows an embodiment of a computing system.

### DETAILED DESCRIPTION

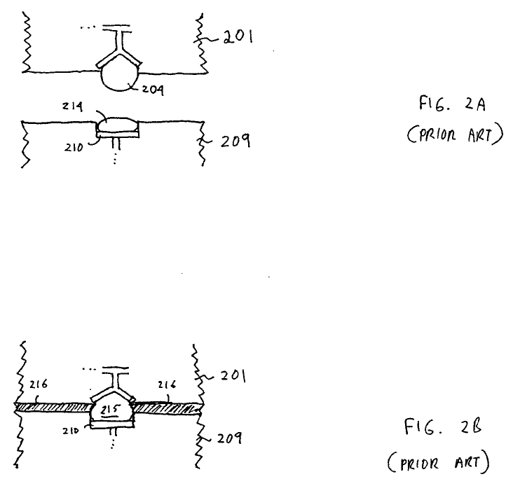

FIGS. 2a and 2b show the bonding of a semiconductor IC bump 204 to a package substrate pad 210, and, the problems associated with the “stress” that the bond may be subjected to. According to the depiction of FIG. 2a, the semiconductor IC 201 is attached to the package substrate 209 by aligning the semiconductor IC 201 and package substrate 209 such that when the semiconductor IC 201 is moved toward the package substrate 209, the semiconductor IC's bumps (such as bump 204) make contact with their respective package substrate pads (such as pad 210). Note that the package substrate pad 210 may include solid solder or solder flux (e.g., in the shape of a bump 214).

Then, as shown in FIG. 2b, energy (i.e., the form of heat, applied pressure, etc.) is applied that causes the semiconductor IC bump 204 (if made of a soft conductive material) and underlying solder bump 214 (if any) to deform so as to form a bond 215 that makes good electrical contact with the package substrate pad 210. A solder mask 216 layer may help in the formation of a package substrate bump 214 prior to the application of the semiconductor IC 201 to the substrate 209, and/or, prevent the substance of the bond 215 from flowing to other neighboring bonds during the bonding process.

A problem, however, is the presence of a “mismatch” between the coefficient of thermal expansion (CTE) of the semiconductor IC 201 and the CTE of the package substrate 209. The CTE of a specific item of matter is an indicator of the extent to which that item of matter will expand in response to a thermal change. If the CTE of the semiconductor IC 201 is different than the CTE of the package substrate 209, the semiconductor IC 201 and substrate 209 will expand/contract by different amounts, which, in turn, results in stress applied to the bond 215 and the regions of the semiconductor IC 201 and package substrate 209 that are proximate to the bond 215.

Because the semiconductor IC 201 may be particularly sensitive to such stresses (e.g., because of the fine line widths associated with the wiring within its multi-layer structure), the semiconductor IC 201 may become permanently damaged from heat that is applied during: 1) the bonding of the semiconductor IC 201 to the package substrate 209; 2) the bonding of the package to a larger electronic system (e.g., the solder of the balls of the semiconductor IC's ball grid array); and/or, 3) the operation of the semiconductor IC itself (e.g., operation of the semiconductor IC in a high ambient temperature external to the package). A layer of underfill 216 that fills the spaces between the bonds, the semiconductor IC and the package substrate 209 may help alleviate the stress applied to the semiconductor IC, but, the semiconductor IC may still be damaged as result of applied thermal environments that may be fairly characterized as “non extreme”.

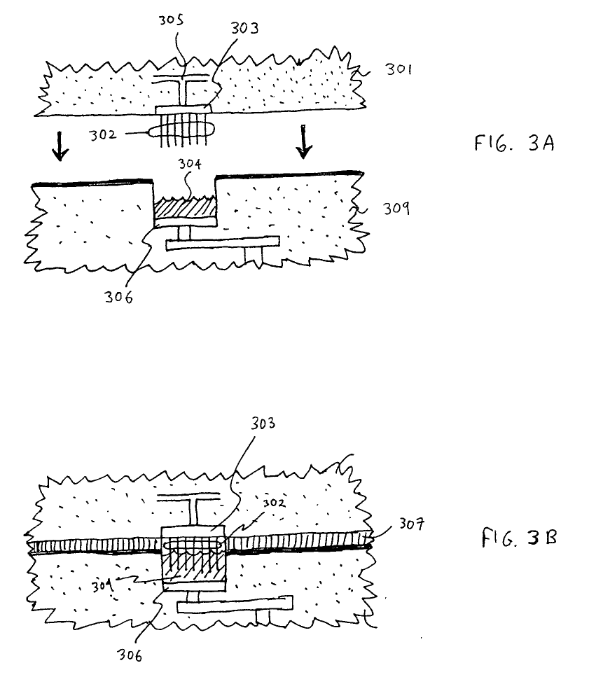

FIGS. 3a and 3b demonstrate an improved approach in which electrically conductive Carbon nanotubes (CNTs) oriented upright from the semiconductor IC or package substrate are inserted into a liquid pool of solder (or perhaps other conductive material) residing in the package substrate or semiconductor IC, respectively, in order to reduce the stress applied to the semiconductor IC when harsh thermal conditions apply. Moreover, with the finger like CNTs being significantly immersed in the pool of conductive liquid, electrical current that flows between the semiconductor IC and package substrate will have a significant surface area over which to flow through the CNT/liquid interface; which, in turn, corresponds to a low “contact” resistance between the CNTs and the liquid.

A Carbon nanotube (CNT) can be viewed as a sheet of Carbon that has been rolled into the shape of a tube (end capped or non-end capped). CNTs having certain properties (e.g., a “metallic” CNT having electronic properties akin to a metal) may be appropriate for certain applications while CNTs having certain other properties (e.g., a “semiconducting” CNT having electronic properties akin to a semiconductor) may be appropriate for certain other applications. CNT properties tend to be a function of the CNT's “chirality” and diameter. The chirality of a CNT characterizes its arrangement of carbon atoms (e.g., arm chair, zigzag, helical/chiral). The diameter of a CNT is the span across a cross section of the tube. According to various embodiments described in detail further below, metallic CNTs are employed. Conceivably, conductively doped semi-conducting CNTs may be used in the alternative.

Referring first to FIG. 3a, a collection of electrically conductive CNTs 302 that extend off the face of a pad 303 formed on the semiconductor IC 301 are aligned with a pool of liquid solder (or other electrically conductive material in the liquid phase) 304 formed in the package substrate 309. The pad 303 formed on the semiconductor IC 301 essentially corresponds to an I/O pad that is electrically coupled to one or more wires 305 within the semiconductor IC's multi-layer structure. Likewise, a pad 306 that helps form or support the bottom the pool 304 is electrically coupled to at least one of the package's external electrical contact structures (e.g., a ball, a pin, a lead, etc.).

Referring to FIG. 3b, when the semiconductor IC 301 is attached to the substrate 309, the conductive CNTs 302 are inserted into the pool of conductive liquid 304, which, essentially corresponds to an electrical connection being made between the conductive CNTs 302 and the pool of conductive liquid 304. Because of the electrical connection that exists between the CNTs 302 and the conductive liquid 304, pad 303 is electrically coupled to pad 306, which, in turn, corresponds to the electrical coupling of the semiconductor's I/O wiring to a package's external electrical contact structure.

According to one embodiment, the attachment of the semiconductor IC 301 to the package substrate 309 forms a sealed chamber. Because the chamber is sealed, the liquid pool is confined to the chamber. As such the liquid pool 304 is free to remain in the liquid phase during and after any packaging and assembly processing, and, even during normal operation of the semiconductor IC 301. By keeping the pool 304 in the liquid phase, unlike prior art implementations as discussed with respect to FIGS. 2a and 2b, stress is largely removed from the electrical coupling formed between the semiconductor IC 301 and the package substrate 309.

That is, any CTE mismatch between the semiconductor IC 301 and the package substrate 309 is easily adapted to by the electrical connection formed in FIG. 3b because the conductive CNTs 301 are free to “move” within the pool of conductive liquid 304 (i.e., the electrical connection is not a “hard physical” contact). Thus, for example, if the package substrate 309 where to have a higher CTE than the semiconductor IC 301, the width of the chamber might expand at a greater rate than the distance between the conductive CNTs 302; or, if the package substrate 309 where to have a lower CTE than the semiconductor IC 301, the width of the chamber might expand at a lesser rate than the distance between the conductive CNTs 302. Either way, the electrical contact between the semiconductor IC and package substrate will be largely free of stress because of the fluidity of the liquid 304.

In alternative implementations, the conductive liquid 304 is expected to have solidified at least by the time the semiconductor IC 301 is being operated (e.g., solidification occurs shortly before or after the packaging process is completed). In this case, the CNTs 302 will be “held in place” by the solidified liquid material. The ability to handle CTE mismatches between the semiconductor IC 301 and package substrate 309 in nevertheless expected to be acceptable because CNTs are sufficiently “flexible and finger-like” and are therefore expected to easily bend in response to the CTE mismatch.

Note that an attachment layer 307 may be formed to physically attach the semiconductor IC 301 and package substrate 309 together. According to one embodiment, the attachment layering 307 is initially formed on the package substrate 309. When the semiconductor IC 301 and package substrate 309 are mated together, the attachment layer 307 forms a physical bond between the semiconductor IC 301 and package substrate 309. Here, depending on the attachment layer's material composition (e.g., various type of polymers), some form of additional treatment (e.g. heat) may be applied to help secure the physical bond between the semiconductor IC 301 and the package substrate 309.

Also, note that the attachment layer 307 is preferably a material that absorbs CTE mismatch induced stress at the interface between the semiconductor IC 301 and the package substrate 309, and/or, transfers such stress away from the semiconductor IC 301 toward the package substrate 309. In an alternate approach, the attachment layer 307 may be initially formed on the semiconductor IC 301 rather than the package substrate.

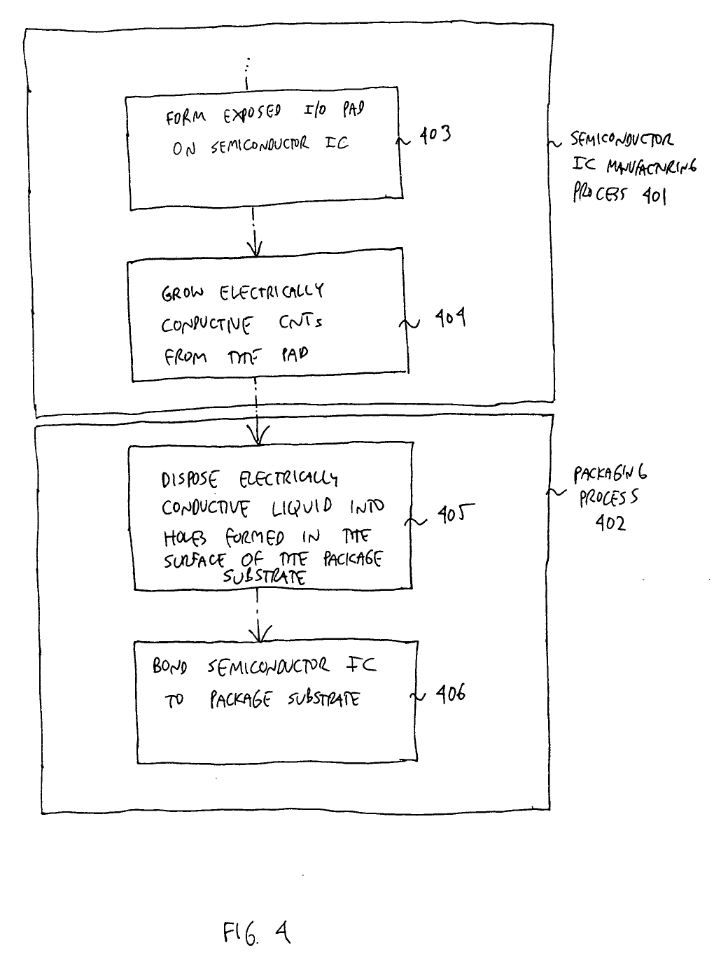

FIG. 4 shows relevant portions of semiconductor IC manufacturing 401 and packaging processes 402 that together effect the formation of a semiconductor IC 301 and packaging substrate 309 electrical interconnect with conducting CNTs inserted in a pool of conductive liquid. According to the methodology of FIG. 4, an externally exposed pad (e.g., pad 303 of FIG. 3a) is formed 403 on the semiconductor IC. The pad 303 is made of one or more electrically conductive materials such as a metal or metal alloy. Vertically oriented electrically conductive CNTs are then grown 404 from the electrically conductive pad.

Growth of electrically conductive CNTs from a layer of metal have already been published. For example, in M. Nihei et al., “Carbon Nanotube Vias For Future LSI Interconnects”, Proceedings of the IEEE 2004 International Interconnect Technology Conference, June 2004, pgs. 251-253, a process for growing bundles of vertically oriented CNTs from a Nickel (Ni) or Cobolt (Co) catalyst layer is described. According to the process taught by Nihei et al. CNT bundles of multi-walled nanotubes (of about 10 nm in outer diameter) were selectively grown (in via holes) by using hot-filament chemical vapor deposition (HF-CVD). The HF-CVD process included a gas source containing a mixture of C₂H₂, Ar and H₂; a chamber pressure of 1 kPa; and, a substrate temperature of 540° C. during CNT growth. The catalyst layer was formed over a Titanium (Ti) contact layer that was formed over a Copper (Cu) metal layer.

Before attachment of the semiconductor IC to the package substrate, electrically conductive liquid is disposed 405 into holes formed in the surface of the package substrate that couples to the semiconductor IC. According to one embodiment, a conductive material having a low melting point is used for the liquid that forms the electrically conductive pool.

For example, according to one approach the liquid pool is formed from a Gallium alloy. Gallium is a semi-conducting material with a low melting point (approximately 30° C.). It is possible to alloy or dope Gallium (Ga) with one or more other materials so as to create a material having sufficiently high electrical conductivity for an IC/substrate contact yet low melting point temperatures for formation of a liquid conducting pool. For example, Gallium—Indium (Galn) alloys exhibit electrical conductivities over a range of about 5-20 μΩ-cm and melting points over a range of about 15°-155° C. depending on the relative mixturing of the Gallium and Indium. Other alloys may be crafted that exhibit melting points in the 150°-250° C. range. Notably, besides Gallium alloys, materials used in traditional solders (e.g., PbSn, high lead, Copper-Tin, Silver-Tin, Indium-Tin, Gold-Tin (with melting points >250° C. such as approximately 280° C.), etc) are also suitable.

According to one approach, the disposition 405 of the conductive liquid in the package substrate's holes involves the heating of the package substrate so as to covert the conductive pool material from the solid phase to the liquid phase. That is, for example, the substrate may be manufactured with the liquid pool material existing as a solid phase layer in a via (a “hole”) formed over a conductive “contact” layer in the package substrate. The conductive contact layer (e.g., pad 306 in FIGS. 3a and 3b) is coupled to wiring within the package substrate. Immediately prior to the attachment of the semiconductor IC die to the package substrate, the package substrate is heated to effectively melt the pool material into the liquid phase. Thus, essentially, the pools are formed by first manufacturing a via with the liquid pool material “frozen” in the via; then, immediately prior to the attachment of the IC die to the package substrate, the package substrate is heated to form a pool of conductive liquid in the via.

According to another approach, the substrate is manufactured with “empty vias” (embedded in the package substrate itself or effectively formed through the use of solder masks) and liquid solder is flowed into the holes immediately prior to attachment of the IC die to the package substrate.

At some point during the packaging process, the semicondcutor IC is aligned with the package substrate such that the vertically oriented CNTs will be inserted into their corresponding pool of conductive liquid. The semiconductor IC is then bonded 406 to the package substrate which includes the insertion of the CNTs into their corresponding liquid pools.

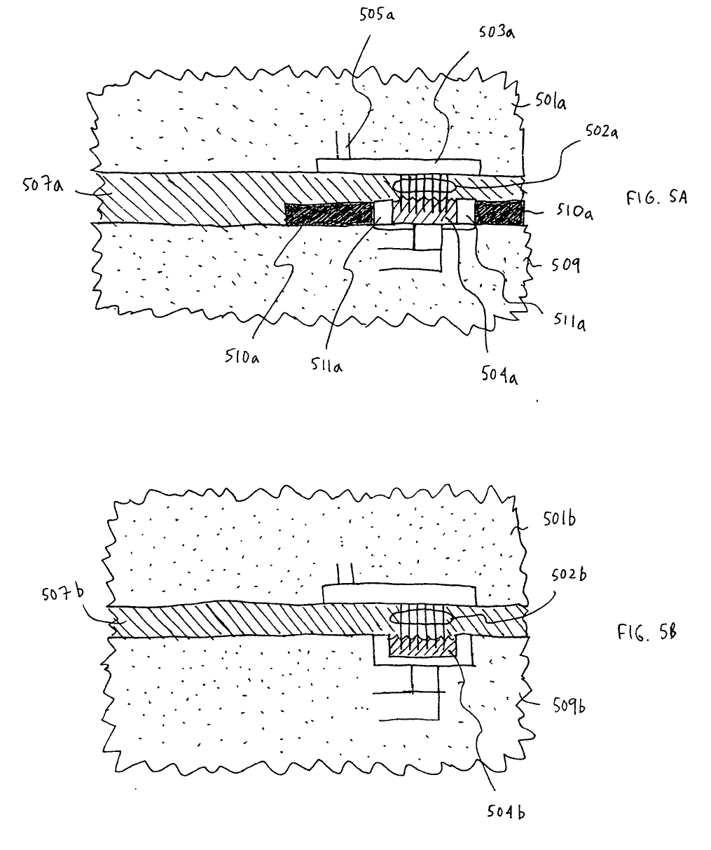

FIGS. 5a and 5b show a pair of more detailed embodiments of a CNT/liquid contact between a semiconductor IC and a package substrate. According to the embodiment of FIG. 5a, the top level of the pool of electrically conductive liquid 504a is effectively above the package substrate 509a because of the presence of solder masks 510a. Here, electrically conductive (e.g., metallic) posts 511a formed on the package substrate 509a and line the insides of the solder mask 510a to help form the chamber within which the electrically conductive pool. The metal posts 511a are electrically coupled to the corresponding wiring within the package substrate 509a so that there is electrical coupling from the package's external electrical contact structures through the conductive liquid 504, CNTs, 502a, semiconductor IC 503a I/O and internal wiring 505a.

FIG. 5b shows an embodiment where the conductive pool 504b is embedded in the package substrate 509b itself. Here, metallurgy is formed in the surface of the package substrate 509b to effectively create the pool's chamber. In both of the embodiments of FIGS. 5a and 5b, the attachment or “underfill” layers 507a,b are optional. The underfill layer 507a,b may be made of an electrically insulating polymer that is present on the package substrate 509a,b prior to the attachment process; or, presented to the IC/package interface during the attachment process. If the former approach is employed (prior to attach), the polymer is cured during the attachment process so that it can flow around the IC/package contacts. If the later approach is employed (during attach), capillary forces are used to assist in the flow of the underfill around the contacts.

FIGS. 3a and 3b can also be interpreted as showing that vertically oriented electrically conductive CNTs can be grown from the package substrate side and a pool of electrically conductive liquid can be formed in vias located on the surface of the semiconductor IC. That is item 301 can be viewed as the package substrate and item 309 can be viewed as the semiconductor IC. Here, for example, growth of the CNTs can be performed as described above (e.g., by HF-CVD of a C₂H₂, Ar and H₂ gas over a Co or Ni catalyst layer over a Ti layer). Likewise, the pools of liquid may be formed as described above (e.g., by solid to liquid phase conversion during the packaging process, or, fluid flow into surface vias during the packaging process).

With respect to the “designed for” state of the CNT/pool contact during normal operation of the semiconductor IC, a first embodiment would design for liquid phase (i.e., the CNTs are immersed in a pool of liquid during normal operation of the semiconductor IC). In a second embodiment, the state of the CNT/pool contact is designed such that the “pool” is the solid phase. According to the second embodiment, the pool is in the liquid phase during the packaging process while the CNTs are being immersed in the liquid pool. Afterward (e.g., after the chip is bonded to the packaging substrate), the liquid pool is allowed to “freeze” so as to solidly bind the bundle of CNTs.

The former embodiment should exhibit better TCE mismatch handling as compared to the first embodiment, because, in the first embodiment the CNTs are free to move in the liquid owing to thermal induced stresses at the IC/package interface; while, in the second embodiment are bound in solid material. Because the CNTs are finger-like, they may demonstrate sufficient flexibility to handle thermal stresses even though they are bound to a solid material. The first embodiment, however, places greater emphasis on forming a well-sealed (e.g., “hermetically sealed”) chamber than the second embodiment.

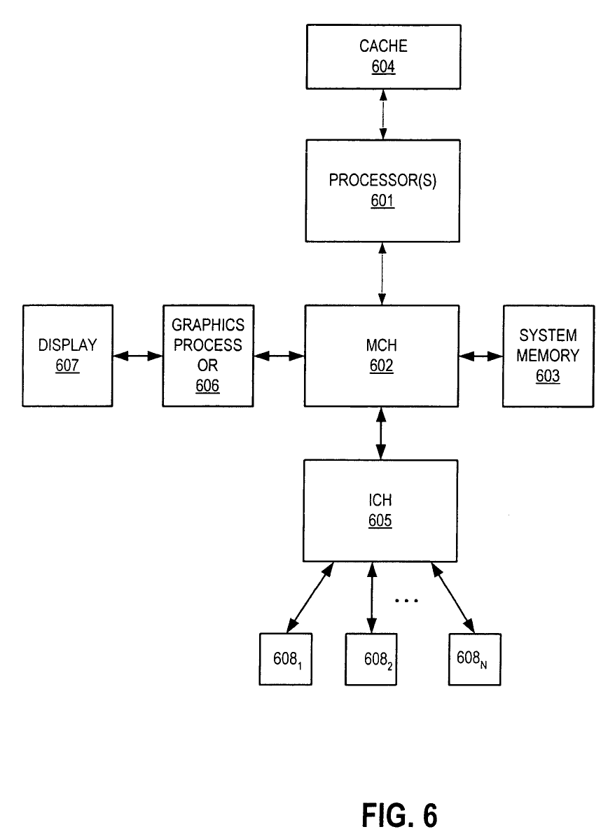

FIG. 6 shows an embodiment of a computing system. The exemplary computing system of FIG. 6 includes: 1) one or more processors 601; 2) a memory control hub (MCH) 602; 3) a system memory 603 (of which different types exist such as DDR RAM, EDO RAM, etc,); 4) a cache 604; 5) an I/O control hub (ICH) 605; 6) a graphics processor 606; 6) a display/screen 607 (of which different types exist such as Cathode Ray Tube (CRT), Thin Film Transistor (TFT), Liquid Crystal Display (LCD), DPL, etc.; 8) one or more I/O devices 608.

The function of a semiconductor die that is electrically coupled to its packaging through CNTs as described above may be one or more of any of a wide number of functions for which semiconductor ICs are designed. For example, the semiconductor IC may be used to implement one or more of processors 601, MCH 602, system memory 603, cache 604, ICH 605, graphics processor 606 or I/O devices 608. The following is a description of some of these components.

The one or more processors 601 execute instructions in order to perform whatever software routines the computing system implements. The instructions frequently involve some sort of operation performed upon data. Both data and instructions are stored in system memory 603 and cache 604. Cache 604 is typically designed to have shorter latency times than system memory 603. For example, cache 604 might be integrated onto the same silicon chip(s) as the processor(s) and/or constructed with faster SRAM cells whilst system memory 603 might be constructed with slower DRAM cells.

By tending to store more frequently used instructions and data in the cache 604 as opposed to the system memory 603, the overall performance efficiency of the computing system improves.

System memory 603 is deliberately made available to other components within the computing system. For example, the data received from various interfaces to the computing system (e.g., keyboard and mouse, printer port, LAN port, modem port, etc.) or retrieved from an internal storage element of the computing system (e.g., hard disk drive) are often temporarily queued into system memory 603 prior to their being operated upon by the one or more processor(s) 601 in the implementation of a software program. Similarly, data that a software program determines should be sent from the computing system to an outside entity through one of the computing system interfaces, or stored into an internal storage element, is often temporarily queued in system memory 603 prior to its being transmitted or stored.

The ICH 605 is responsible for ensuring that such data is properly passed between the system memory 603 and its appropriate corresponding computing system interface (and internal storage device if the computing system is so designed). The MCH 602 is responsible for managing the various contending requests for system memory 603 access amongst the processor(s) 601, interfaces and internal storage elements that may proximately arise in time with respect to one another.

One or more I/O devices 608 are also implemented in a typical computing system. I/O devices generally are responsible for transferring data to and/or from the computing system (e.g., a networking adapter); or, for large scale non-volatile storage within the computing system (e.g., hard disk drive). ICH 605 has bi-directional point-to-point links between itself and the observed I/O devices 608, although, more traditional designs used a bus for interconnecting multiple I/O devices into the computing system.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. A packaged integrated circuit (IC) comprising an integrated circuit that is electrically coupled to its package's wiring with Carbon nanotubes (CNTs) placed within an electrically conductive material.

2. The integrated circuit of claim 1 wherein said material is in the liquid phase.

3. The integrated circuit of claim 1 wherein said material comprises Gallium.

4. The integrated circuit of claim 3 wherein said material comprises Indium.

5. The integrated circuit of claim 1 wherein said material has a melting point between 15° and 250° C. inclusive.

6. The integrated circuit of claim 5 wherein said material has melting point between 150° and 250° C. inclusive.

7. The integrated circuit of claim 5 wherein said material has melting point between 15° and 155° C. inclusive.

8. The integrated circuit of claim 1 wherein said material in the solid phase.

9. The integrated circuit of claim 1 wherein said Carbon nanotubes sprout from said integrated circuit.

10. The integrated circuit of claim 1 wherein said Carbon nanotubes sprout from said package's susbtrate.

11. A method, comprising:
electrically coupling a semiconductor IC to its package by inserting Carbon nanotubes into an electrically conductive material that is in a liquid phase.

12. The method of claim 11 wherein said material has a melting point between 15° and 250° C. inclusive.

13. The method of claim 11 wherein said material has melting point between 150° and 250° C. inclusive.

14. The method of claim 11 wherein said material has melting point between 15° and 155° C. inclusive.

15. The method of claim 11 wherein said material comprises Gallium.

16. The method of claim 15 wherein said material comprises Indium.

17. An apparatus, comprising:
a computing system comprising a packaged integrated circuit having circuitry to perform a memory controller function, said integrated circuit being electrically coupled to its package's wiring with Carbon nanotubes (CNTs) placed within an electrically conductive material, said packaged integrated circuit coupled to DDR random access memory.

18. The apparatus of claim 17 wherein said material is in the liquid phase.

19. The apparatus of claim 17 wherein said material comprises Gallium.

20. The apparatus of claim 19 wherein said material comprises Indium.

21. The apparatus of claim 17 wherein said material has a melting point between 15° and 250° C. inclusive.

22. The apparatus of claim 21 wherein said material has melting point between 150° and 250° C. inclusive.

23. The apparatus of claim 21 wherein said material has melting point between 15° and 155° C. inclusive.

24. The apparatus of claim 17 wherein said material in the solid phase.
